(19) United States
(12) Patent Application Publication
(10) Pub. No.: US 2012/0145853 A1
(43) Pub. Date: Jun. 14, 2012

(54) MOUNTING APPARATUS FOR DATA STORAGE DEVICE

(75) Inventors: ZHEN-XING YE, Shenzhen City (CN); ZI-XUAN ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/972,510

(22) Filed: Dec. 19, 2010

(30) Foreign Application Priority Data
Dec. 9, 2010 (CN) 201010580861.3

(51) Int. Cl. H05K 7/14

(52) U.S. Cl. 248/224.8

(57) ABSTRACT

A mounting apparatus for a data storage device includes a bracket, two slide boards, and a number of fasteners. The data storage device includes opposite sidewalls each defining a number of fixing holes. The bracket includes two mounting arms each defining a number of through holes. The slide boards are slidably mounted to the mounting arms before fixed to the bracket via the plurality of fasteners. The data storage device and the slide boards are capable of adjusting positions relative to each other such that at least one set of one of the fixing holes, one of the through holes, and one of the mounting holes, corresponding to one of the sidewalls, are aligned with each other. One of the plurality of fasteners fastens the corresponding mounting arm and slide board to the corresponding sidewall via extending through the set of aligning holes.

### BACKGROUND

1. Technical Field

The disclosure relates to a mounting apparatus for data storage devices.

2. Description of Related Art

Generally speaking, a bracket is mounted in a computer enclosure, to which a storage device will be attached. A distance between the storage device and a front side of the bracket can influence the efficiency of heat dissipation in the computer. However, a conventional bracket has a fixed size and configuration. Any variance in configuration of a storage device mounted in the bracket could change the distance between the storage device and the front side of the bracket. As a result, a different bracket may be needed, which can be quite inconvenient and costly.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a mounting apparatus, together with a data storage device.

FIG. 2 is an assembled, isometric view of FIG. 1.

FIG. 3 is a use state view of FIG. 2.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

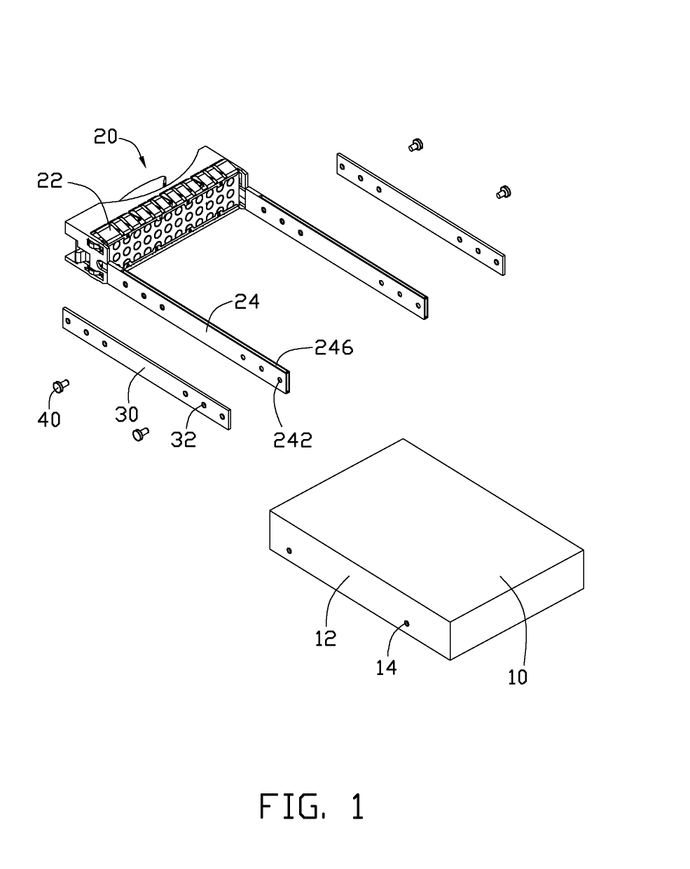

Referring to FIG. 1, a mounting apparatus is provided to mount a data storage device 10. The mounting apparatus includes a bracket 20, two slide boards 30 slidably mounted to the bracket 20, and a plurality of fasteners 40. In this embodiment, the fasteners 40 are screws.

The storage device 10 includes two opposite sidewalls 12. Each sidewall 12 defines two fixing holes 14.

The bracket 20 includes a front panel 22 and two mounting arms 24 substantially perpendicularly extending from opposite ends of the front panel 22. Each mounting arm 24 defines a plurality of through holes 242, adjacent to opposite ends of the mounting arm 24, correspondingly. A top side of each mounting arm 24 defines a slide slot 246. The slide slots 246 of the mounting arms 24 extend along a longitudinal direction of the corresponding mounting arms 24 and through rear ends of the mounting arms 24 opposite to the front panel 22. The slide slots 246 communicate with the corresponding through holes 242 in the same mounting arms 24.

Each slide board 30 defines a plurality of mounting holes 32, adjacent to opposite ends of the slide board 30, correspondingly.

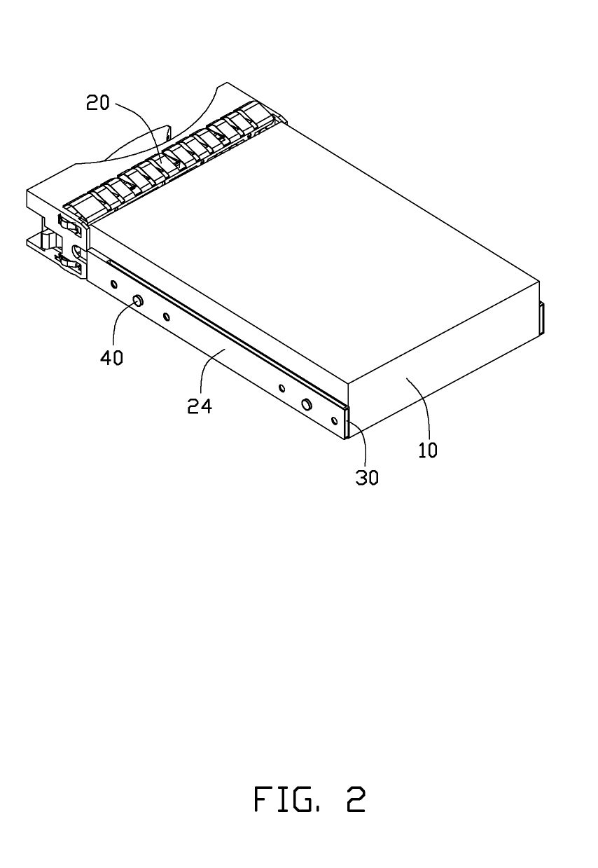

Referring to FIG. 2, in assembly, each slide board 30 is slidably engaged in the corresponding slide slot 246 of the bracket 20, with the mounting holes 32 aligned with the corresponding through holes 242. The data storage device 10 is sandwiched between the mounting arms 24 of the bracket 20, with the sidewalls 12 abutting against inner sides of the mounting arms 24. Therefore, the fixing holes 14 of the data storage device 10 align with the corresponding through holes 242 of the mounting arms 24 and the corresponding mounting holes 32 of the slide boards 30. The fasteners 40 are extended through the mounting holes 32 and the through holes 242, and then, engaged in the fixing holes 14 to mount the data storage device 10 to the bracket 20.

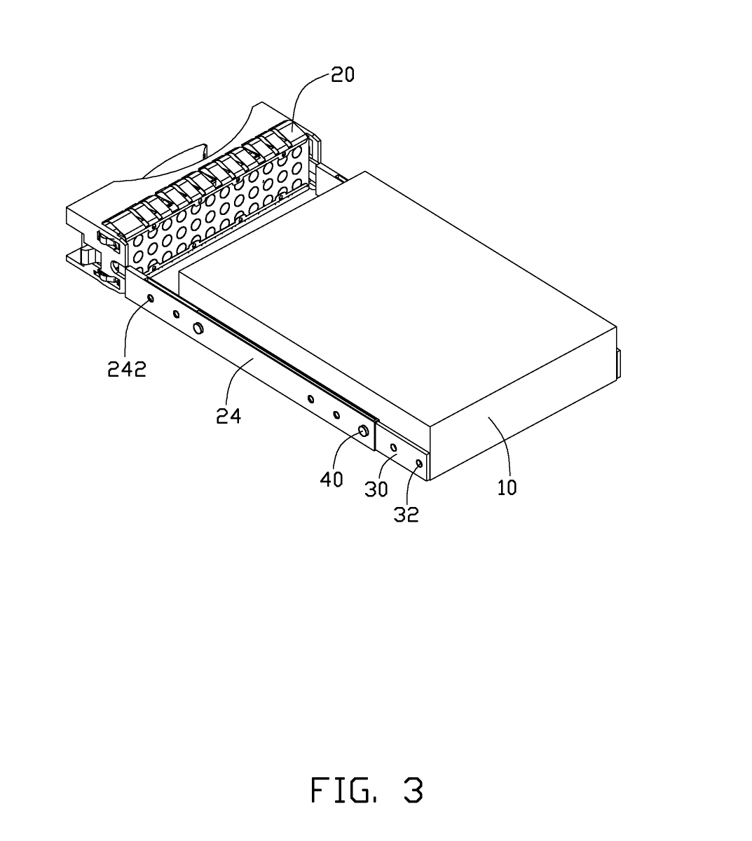

Referring to FIG. 3, to adjust a distance between the data storage device 10 and the front panel 22 of the bracket 20, the fasteners 40 are released and the data storage device 10 is detached from the bracket 20. The data storage device 10 and the slide boards 30 are capable of moving along the mounting arms 24 before fixed to the bracket 20 by the plurality of fasteners 40. The data storage device 10 and the slide boards 30 are capable of adjusting positions relative to each other such that at least one set of one of the fixing holes 14, one of the through holes 242, and one of the mounting holes 32, corresponding to one of the sidewalls 12 of the data storage device 10, are aligned with each other. One of the plurality of fasteners 40 fastens the corresponding mounting arm 24 and slide boards 30 to the corresponding sidewall 12 of the data storage device 10 via extending through the set of aligning holes. Therefore, the data storage device 10 is then mounted to the bracket 20 by the fasteners 40.

It is believed that the present embodiment and its advantages will be understood from the foregoing description, and it will be apparent that various changes may be made thereto without departing from the spirit and scope of the description or sacrificing all of their material advantages, the example hereinbefore described merely being exemplary embodiment.

What is claimed is:

1. A mounting apparatus for a data storage device, the data storage device comprising opposite sidewalls each defining a plurality of fixing holes, the mounting apparatus comprising:
a bracket comprising two opposite mounting arms, each mounting arm defining a plurality of through holes;
two slide boards slidably mounted to the mounting arms, correspondingly, each slide board defining a plurality of mounting holes; and
a plurality of fasteners; wherein the data storage device is sandwiched between the mounting arms, with the sidewalls abutting against inner sides of the mounting arms, the data storage device and the slide boards are capable of moving along the mounting arms before fixed to the bracket via the plurality of fasteners, and wherein the data storage device and the slide boards are capable of adjusting positions relative to each other such that at least one set of one of the fixing holes, one of the through holes, and one of the mounting holes, corresponding to one of the sidewalls of the data storage device, are aligned with each other and one of the plurality of fasteners fastens the corresponding mounting arm and slide board to the corresponding sidewall of the data storage device via extending through the set of aligning holes.

2. The mounting apparatus of claim 1, wherein each mounting arm defines a slide slot communicating with the through holes, the slide boards are slidably received in the slide slots.

3. The mounting apparatus of claim 2, wherein the slide slots longitudinally extend along the corresponding mounting arms and through rear ends of the mounting arms.

4. The mounting apparatus of claim 1, wherein the bracket comprises a front panel, the mounting arms substantially perpendicularly extend from opposite ends of the front panel.

5. The mounting apparatus of claim 4, wherein a top side of each mounting arm longitudinally defines a slide slot with a rear end of the slide slot extending through an end of the mounting arm opposite to the front panel, and the slide slot communicates with the through holes of the mounting arm, the slide boards are slidably received in the slide slots, and operable to extending out of the slide slots through the rear ends of the mounting arms.
